(19) United States
(12) Patent Application Publication
(10) Pub. No.: US 2025/0140540 A1
(43) Pub. Date: May 1, 2025

(54) SUBSTRATE PROCESSING SYSTEM WITH CAPABILITIES FOR DETECTING WHETHER A WAFER IS DECHUCKED AND A METHOD THEREOF

(71) Applicant: ASM IP Holding B.V., Almere (NL)

(72) Inventors: Sergei Golovkov, Tokyo (JP); Hoyoun Jang, Hwaseong-si (KR)

(21) Appl. No.: 18/926,695

(22) Filed: Oct. 25, 2024

Related U.S. Application Data
(60) Provisional application No. 63/546,307, filed on Oct. 30, 2023.

(51) Int. Cl. H01J 37/32; G01R 25/00; H01L 21/67

(52) U.S. Cl. CPC H01J 37/32926; G01R 25/005; H01J 37/32183; H01L 21/67259

(57) ABSTRACT

A substrate processing system with capabilities to detect whether a wafer is dechucked during process is disclosed. An embodiment of the present disclosure's system comprises a reaction chamber provided with an upper electrode and a lower electrode, and configured to process a wafer, a radio frequency generator configured to generate a high frequency power to process the wafer in the reaction chamber, a matching unit disposed between the reaction chamber and the generator and configured to match the generated high frequency power from the generator for use in the reaction chamber, a phase shift detector connected to the reaction chamber in parallel and configured to detect a phase shift between a signal going into the upper electrode and a signal coming out of the lower electrode, and a controller connected to the phase shift detector and configured to receive parameters, to determine and to display the status of the wafer.

### CROSS-REFERENCE TO RELATED APPLICATIONS

This application claims priority to U.S. Provisional Patent Application Ser. No. 63/546,307 filed Oct. 30, 2023 and titled SUBSTRATE PROCESSING SYSTEM WITH CAPABILITIES FOR DETECTING WHETHER A WAFER IS DECHUCKED AND A METHOD THEREOF, the disclosure of which is hereby incorporated by reference in its entirety.

### FIELD OF INVENTION

The present disclosure relates to a substrate processing system, more particularly to a substrate processing system with capabilities to detect if a wafer currently in process is dechucked or not without any interference to the process.

### BACKGROUND OF THE DISCLOSURE

During deposition processes, a silicon wafer sometimes gets dechucked (dislodged from a holder of the silicon wafer) due to insufficient chucking force or perturbation of the plasma parameters and wafer dechucking can result in poor film uniformity and reduce yield.

A non-chucking event (which means an event when a wafer which is put on a holder in a deposition apparatus is dislodged from the holder from the start of process) and a dechucking event (which means an event when a wafer got dislodged from its holder during the process) can be detected in deposition phase by observing reflected power of Low Radio Frequency (LRF) in a Plasma Enhanced Chemical Vapor Deposition (PECVD) process. However, a Plasma Enhanced Atomic Layer Deposition (PEALD) process has no LRF module, so it would not be possible to detect bad chucking during the PEALD process with the method used in PECVD process.

Therefore, a system and method to detect whether a wafer in the system is dechucked (or non-chucked) during PEALD process is needed.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a substrate processing system with capabilities to detect whether a wafer is dechucked during processing comprising a reaction chamber provided with an upper electrode and a lower electrode, and configured to process a wafer, a radio frequency (RF) generator configured to generate a high frequency power to process the wafer in the reaction chamber, a matching unit disposed between the reaction chamber and the RF generator and configured to adjust the impedance of the reaction chamber for the generated high frequency power to be more effective in the processing, a phase shift detector connected to the reaction chamber in parallel and configured to detect a phase shift between a signal going into the upper electrode and a signal coming out of the lower electrode and a controller connected to the phase shift detector and configured to receive parameters, to determine and to display the status of the wafer.

In at least one aspect, the substrate processing system further comprising a first attenuator disposed between the upper electrode and the phase shift detector and a second attenuator disposed between the phase shift detector and the lower electrode.

In accordance with another embodiment there may be provided, a method to detect whether a wafer is dechucked in a substrate processing system comprises receiving a first threshold, a second threshold and a minimum time length, measuring phase shift degrees from the upper electrode and the lower electrode of the reaction chamber, determining whether the measured phase shift degrees are not within the first and the second thresholds and last longer than the minimum time length is true and displaying a dechucked status if determined to be true and repeat measuring if determined to be false.

In accordance with another embodiment there may be provided, a substrate processing system with capabilities to detect whether a wafer is dechucked during processing, the system comprising a reaction chamber provided with an upper electrode and a lower electrode, and configured to process a wafer, a radio frequency (RF) generator configured to generate a high frequency signal to process the wafer in the reaction chamber, a matching unit disposed between the reaction chamber and the RF generator and configured to adjust the impedance of the reaction chamber for the generated high frequency power to be more effective in the processing, a network analyzing unit connected to the reaction chamber in parallel and configured to detect a transmission coefficient of the reaction chamber and a controller connected to the network analyzing unit and configured to receive parameters, to determine and to display the status of the wafer.

In at least one aspect, the substrate processing system further comprising: a first low pass filter (LPF) disposed between the upper electrode and the network analyzing unit and a second LPF disposed between the network analyzing unit and the lower electrode.

In at least one aspect, the network analyzing unit is a vector network analyzer.

In at least one aspect, the transmission coefficient is calculated by a formula below, S₂₁=Sₒᵤₜ/Sᵢₙ, (S₂₁: transmission coefficient, Sₒᵤₜ: Signal going out from the first LPF, Sᵢₙ: Signal coming into the second LPF)

In accordance with another embodiment there may be provided, a method to detect whether a wafer is dechucked in a substrate processing system comprises receiving a threshold, measuring a transmission coefficient from the reaction chamber, determining whether the measured transmission coefficient is greater than the threshold is true and displaying dechucked if determined to be true and repeat measuring if determined to be false.

In accordance with another embodiment there may be provided, a substrate processing system with capabilities to detect whether a wafer is dechucked during processing, the apparatus comprises a reaction chamber configured to process a wafer, a radio frequency (RF) generator configured to generate a high frequency power to process the wafer in the reaction chamber, a matching unit disposed between the reaction chamber and the RF generator and configured to adjust the impedance of the reaction chamber for the generated high frequency power to be more effective in the processing, a screen circuit connected to the matching unit in series and configured to produce a reference voltage used for calculating a slope value (b) to determine whether the wafer is dechucked and a controller connected to the screen circuit and configured to monitor the reference voltage and to calculate the slope value and to decide whether the wafer is dechucked.

In at least one aspect, the substrate processing system wherein the screen circuit comprises more than one resistance, more than one capacitor, one or more coils and one or more diodes.

In accordance with another embodiment there may be provided, a method to detect whether a wafer is dechucked in a substrate processing system comprises receiving a predetermined number (N) and a threshold, measuring N reference voltages (V_{ref,i}) from the screen circuit (1≤i≤N), extracting maximum value (V_{max,i}) of each of the N reference voltages (V_{ref,i}) (1≤i≤N), calculating moving average values yₙ (1≤n≤N) with equation below, wherein equation)

$${y}_{n} = \frac{{\sum }_{i = 1}^{n} {V}_{max , i}}{n} ( 1 \leq n \leq N ) ,$$

deriving a slope value b with equation below, wherein equation)

$$b = \frac{N \cdot ( {\sum }_{n = 1}^{N} n \cdot {y}_{n} ) - ( {\sum }_{n = 1}^{N} n ) \cdot ( {\sum }_{n = 1}^{N} {y}_{n} )}{N \cdot ( {\sum }_{n = 1}^{N} {n}^{2} ) - {( {\sum }_{n = 1}^{N} n )}^{2}} ,$$

deciding whether the slope value b is less than the threshold is true; and displaying a dechucked status if decided to be true and repeat receiving if decided to be false.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of a substrate processing system with dechucked-wafer detecting capabilities according to the 1^{st} system embodiment of the present disclosure.

FIG. 2 illustrates an example of how the substrate processing system and the method to detect a dechucked wafer would work according to a 1^{st} method embodiment of the present disclosure.

FIG. 3 (a) illustrates a flowchart of the method to detect a dechucked wafer in a substrate processing system according to a 1^{st} method embodiment of the present disclosure; (b) illustrates an example with values how the method works according to a 1^{st} method embodiment of the present disclosure.

FIG. 4 illustrates an overview of a substrate processing system with dechucked wafer detecting capabilities according to a 2^{nd} system embodiment of the present disclosure.

FIG. 5 illustrates an example of how the substrate processing system and the method to detect a dechucked wafer would work according to a 2^{nd} method embodiment of the present disclosure.

FIG. 6 illustrates a flowchart of the method to detect a dechucked wafer in a substrate processing system according to a 2^{nd} method embodiment of the present disclosure.

FIG. 7 illustrates an overview of a substrate processing system with dechucked wafer detecting capabilities according to a 3^{rd} system embodiment of the present disclosure.

FIG. 8 (a) illustrates an example of High Radio Frequency (HRF) power graphs generated from RF generator for multiple cycles generated from RF generator; (b) illustrates an example of reference voltages (V_{ref}) monitored by the system and each of the extracted maximum values (Vₘₐₓ) from the reference voltages (V_{ref}) according to a 3^{rd} method embodiment of the present disclosure.

FIG. 9 illustrates a flowchart of the method to detect a dechucked wafer in a substrate processing system according to a 3^{rd} method embodiment of the present disclosure.

FIG. 10 (a) illustrates an example of getting slope value b with (N=4) case; (b) illustrates another example of getting slope value b with (N=4) case.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

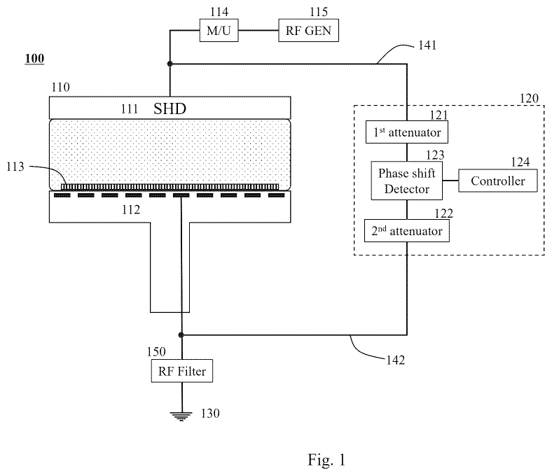

FIG. 1 illustrates a substrate processing system 100 comprising a reaction chamber 110, a radio frequency (RF) generator 115, a matching unit 114, and a monitoring block 120. The reaction chamber 110 may comprise an upper electrode 111 and a lower electrode 112. The upper electrode 111 may be a showerhead, while the lower electrode 112 may be a susceptor. A wafer 113 may be placed on the lower electrode 112.

The RF generator 115 generates RF power. The matching unit 114 may be configured to adjust the impedance of the reaction chamber 110 for the generated RF power to be more effective in the wafer processing and the lower electrode 112 is grounded to the ground 130.

The substrate processing system 100 may also comprise a radio frequency (RF) filter 150. The RF filter 150 may be connected to the lower electrode 112 at one end and to the ground 130 as shown in FIG. 1.

The monitoring block 120 may comprise a phase shift detector 123 and a controller 124 coupled to the phase shift detector 123. The monitoring block 120 may be connected to the reaction chamber 110 in parallel. Additional attenuators 121, 122 may be connected to the phase shift detector 123 in series as shown in FIG. 1.

The phase shift detector 123 monitors and detects how much phase may be shifted from the signal coming through it. The measured phase shift may be shown in an analog or digital form. The phase shift detector 123 may comprise an oscilloscope. The attenuators 121, 122 may attenuate or reduce the amplitude of the signal which passes through it. Instead of attenuators, high voltage probes (not drawn) may be used. The attenuators are used for reducing the signal strength so that any harm that may be done to the shift detector 123 from a high-powered signal would be reduced.

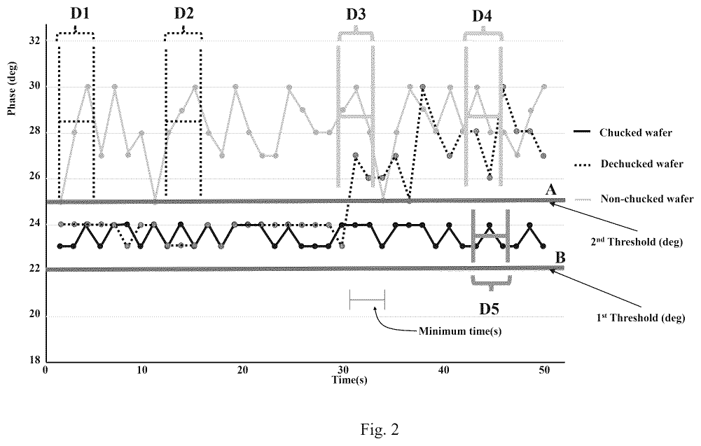

The controller 124 may receive parameters such as 1^{st} threshold (minimum value), 2^{nd} threshold (maximum value), and the length of minimum time (in second). FIG. 2 illustrates an example of how the measured (monitored) phase shift values would be used to decide whether a wafer is dechucked or not.

The 1^{st} and 2^{nd} thresholds (A and B) define the minimum and maximum values (in degrees) respectively so that any phase shifts between B and A would be thought to be a normally chucked wafer. On the other hand, any phase shifts larger than the maximum value (A) may be considered dechucked. The parameter minimum time length is the minimum lasting time for phase shifts which would be used to decide a wafer's dechucking status.

For example, as shown in FIG. 2, the 1^{st} threshold value may be [22 degrees] and the 2^{nd} threshold value to be [25 degrees]. The minimum time length may be [3 cycles] (this time the parameter was set to be the number of cycles for simplicity).

Then the controller 124 measures and monitors the phase shift values picked up from the phase shift detector 123. The periods D1˜D5 last for the minimum time length and periods D1 and D2 may be examples for the ‘Non-chucked wafer’, D3 and D4 for ‘Dechucked wafer’, D5 for ‘Chucked wafer’.

During D1, there are 3 phase shift values such as [25 degrees], [28 degrees] and [30 degrees]. Although [28 degrees] and [30 degrees] are greater than the second threshold, the shift value of the first cycle in D1, i.e., [25 degrees], is equal to the second threshold. This means the controller 124 may not determine the wafer to be dechucked after D1. However, D2 contains phase shift values such as [28 degrees], [29 degrees] and [30 degrees] and all of them are greater than the second threshold. After D2, the controller 124 may determine that the wafer is dechucked.

Although a non-chucking event and a dechucking event is quite different, ‘dechucked’ may be used to mean both a non-chucking event and a dechucking event throughout this disclosure.

D3 contains 3 phase shift values such as [23 degrees], [27 degrees] and [26 degrees]. Although [27 degrees] and [26 degrees] are greater than the second threshold, [23 degrees] is less than the second threshold. Therefore, the controller 124 may not decide wafer to be dechucked after D3. But D4 contains phase shift values such as [28 degrees], [26 degrees] and [30 degrees]. Since all the 3 values are greater than the second threshold, the controller 124 may decide the wafer to be dechucked after D4.

D5 contains 3 phase shift values such as [23 degrees], [24 degrees] and [23 degrees]. Since all of them are within the gap between the first threshold and the second threshold, the controller 124 may not decide the wafer to be dechucked after D5.

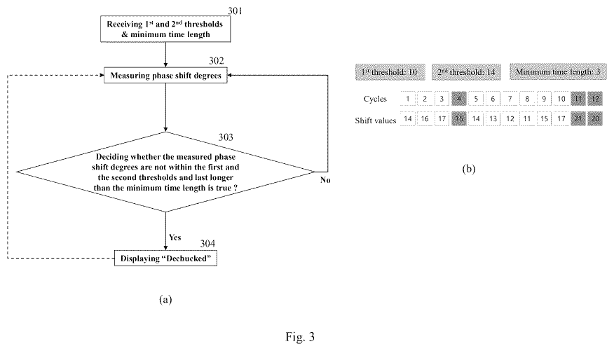

FIG. 3 (a) illustrates the method how to decide whether a wafer is dechucked or not.

In the beginning in a step 301 of the method, the controller 124 may receive parameters such as the first threshold, the second threshold and the minimum time length. The roles of each parameter may be explained above with FIG. 2. In a step 302 of the method, once the parameters are set, the controller 124 may start measuring (or monitoring) the phase shift degrees picked up from the phase shift detector 123. In a step 303 of the method, for every new input of phase shift value (in degrees), the controller 124 may decide whether the measured phase shift values are 1) not within the gap between the first threshold and the second threshold (condition I) and 2) the phase shift values are lasting equal to or longer than the minimum time length (condition II).

FIG. 3 (b) shows an example with values illustrating how the method in FIG. 3 (a) works.

The first threshold is set to [10 degrees] and the second threshold is set to [14 degrees]. The minimum time length is set to [3 cycles]. In cycle 1, a phase shift value [14 degrees] is received but cycle 1's time length is just [1 cycle] (only [14 degrees] so far) so measuring (step 302) may be executed. In cycle 2, a new shift value [16 degrees] is received but cycle 2's time length is [2 cycles] ([14 degrees], [16 degrees] so far) so measuring (step 302) may continue.

In cycle 3, a new shift value [17 degrees] is received and ‘condition II’ is met from cycle 3. Among the three shift values ([14 degrees], [16 degrees], [17 degrees]) in cycle 3's time length, [16 degrees] & [17 degrees] are not within the gap between the first and the second thresholds. Therefore, in a step 302 of the method, the controller 124 may be configured to continues measuring phase shift values.

In cycle 4, a new value [15 degrees] is received and cycle 4's time length has 3 shift values [16 degrees], [17 degrees], [15 degrees]. All the values are not within the gap between the first and the second thresholds. Therefore, in a step 304 of the method, the controller 124 may display “dechucked”.

A dechucked wafer may not usually go back to a “chucked” status once the wafer gets dislodged from its proper position. So, when the controller 124 displays “dechucked”, there may be no need to proceed. But in some specific systems with different requirements, the dechucked wafer might go back to a chucked status. Therefore, in some cases, in steps 304 and 302 of the method, the controller 124 may be configured to continue measuring after displaying “dechucked”.

Let's assume that the controller 124 may be configured to continue after cycle 4 of FIG. 3 (b). In cycle 5, a new value [14 degrees] is received. Since [14 degrees] is not satisfying the ‘condition I’, the controller 124 may be configured to continue measuring without displaying “dechucked”. In cycles 6, 7 and 8, values [13 degrees], [12 degrees] and [11 degrees] are received respectively. All of them do not meet the ‘condition I’.

In cycles 9 and 10, values [15 degrees] and [17 degrees] are received in turn. Since [11 degrees] is included in the cycle 9's and 10's time length, the controller 124 may be configured to measure phase shift values and not to display “dechucked” until cycle 10.

In cycles 11 and 12, new values [21 degrees] and [20 degrees] are received. Since the phase shift values in the time lengths of cycle 11 ([15 degrees], [17 degrees]. [21 degrees]) and cycle 12 ([17 degrees]. [21 degrees], [20 degrees]) meet the ‘condition I’, the controller 124 may be configured to display “dechucked” after cycle 11 and cycle 12. Therefore, as shown in FIG. 3 (b), with the parameters of the first threshold [10 degrees], the second threshold [14 degrees] and minimum time length [3 cycles], the controller 124 may be configured to display “dechucked” only after cycles 4, 11 and 12.

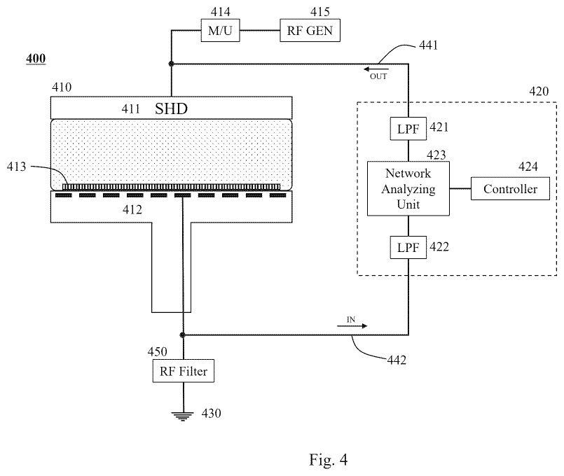

FIG. 4 illustrates a 2^{nd} embodiment of the present disclosure. A substrate processing system 400 comprising a reaction chamber 410, a radio frequency (RF) generator 415, a matching unit 414 and a monitoring block 420. The reaction chamber 410 may comprise an upper electrode 411 and a lower electrode 412. The upper electrode 411 may be a showerhead and the lower electrode 412 may be a susceptor. A wafer 413 may be placed on the lower electrode 412. The substrate processing system 400 may also comprise an RF filter 450 connected to the lower electrode 412 at one end and to a ground 430 at the other end as shown in FIG. 4.

The RF generator 415 may generate RF power. The matching unit 414 may be configured to adjust the impedance of the reaction chamber 410 for the generated RF power to be more effective in the wafer processing and the lower electrode 412 is grounded to the ground 430.

The monitoring block 420 may comprise a network analyzing unit 423 and a controller 424 coupled to the network analyzing unit 423. The monitoring block 420 may be connected to the reaction chamber 410 in parallel. And low pass filter (LPF) 421, 422 may be connected to the network analyzing unit 423 in series as shown in FIG. 4.

The network analyzing unit 423 may be configured to monitor and measure both amplitude and phase properties of signals by using Scattering Parameters (S-parameters) theory. Since explaining S-Parameters theory would be off the subject of the present disclosure, only the result of the theory (i.e., a formula for getting transmission coefficient) would be used. The formula for getting a transmission coefficient for forward transmission could be denoted as S₂₁=S_{transmitted}/S_{incident}. [EQ 1] (S₂₁: transmission coefficient, S_{transmitted}: signal going into the device under test, S_{incident}: signal coming out from the device under test).

The network analyzing unit 423 may be a vector network analyzer. The LPFs 421, 422 may be configured to allow low-frequency signals to pass through while attenuating high-frequency signals.

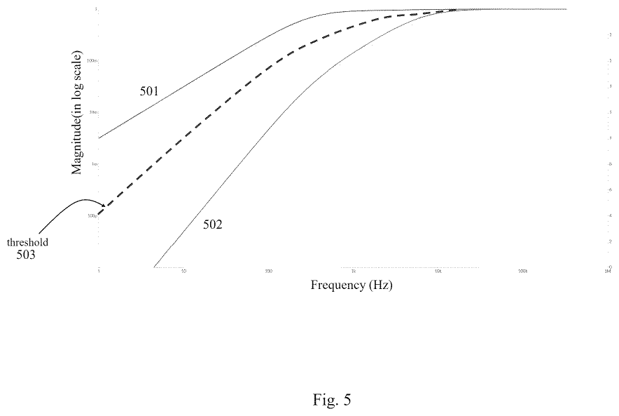

The controller 424 may be configured to receive a parameter such as a threshold value. FIG. 5 illustrates an example of how the measured (monitored) transmission coefficient may be used to decide whether a wafer is dechucked.

Curve 501 may be a curve of transmission coefficient from [EQ 1] when the wafer 413 may be chucked normally and curve 502 may be a curve of transmission coefficient when the wafer 413 may be dechucked. As can be seen in FIG. 5, y-axis is magnitude and x-axis is frequency and the slope of the curve 502 is larger than that of the curve 501.

Curve 503 may be the received parameter (threshold). Any transmission coefficient curve with a slope larger than that of the threshold curve 503 may be decided to be a dechucked wafer and any transmission coefficient curve with a slope smaller than that of the threshold curve 503 may be decided to be a chucked wafer.

The LPFs 421, 422 would attenuate signals with frequency larger than 1 MHz so the frequency range of FIG. 5 may be 1 Hz˜1 MHz. This frequency spectrum would change from system to system for better dechucking detection.

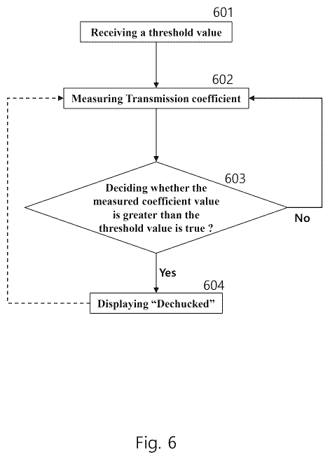

FIG. 6 illustrates the 2^{nd} method embodiment of how to decide whether a wafer is dechucked.

In the beginning, in a step 601 of the method, the controller 424 may receive a parameter such as threshold curve value. In a step 602 of the method, once the parameter is set, the controller 124 may start measuring (or monitoring) the transmission coefficient picked up from the network analyzing unit 423. The network analyzing unit 423 may use [EQ 2] below for getting the transmission coefficient. As can be seen, EQ 2 is derived from EQ 1.

$$Transmission coefficient = {S}_{out} / {S}_{in} ,$$

(Sₒᵤₜ: Signal going out from the first LPF 421,
Sᵢₙ: Signal coming into the second LPF 422) [EQ 2]

After getting transmission coefficient, in a step 603 of the method, the controller 424 may be configured to decide whether the measured transmission coefficient is greater than the threshold value is true. This means that whether the slope of the newly measured transmission coefficient curve is larger than that of the threshold value curve.

If the measured transmission coefficient is greater than the threshold value, in a step 604 of the method, the controller 424 may be configured to display ‘dechucked’. If the measured transmission coefficient is equal to or smaller than the threshold value, in a step 602 of the method, the controller 424 may be configured to continue measuring transmission coefficient without displaying ‘dechucked’.

A dechucked wafer may not usually go back to a “chucked” status once the wafer gets dislodged from its proper position. So, when the controller 424 displays “dechucked”, there may be no need to proceed. But in some specific systems with different requirements, the dechucked wafer might go back to a chucked status. Therefore, just like in steps 604 and 602 of the method, in some cases the controller 424 may be configured to continue measuring after displaying “dechucked”.

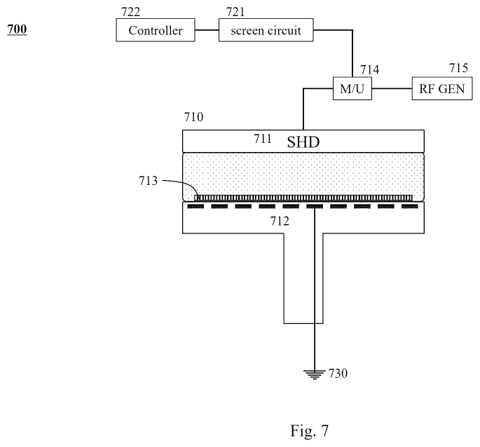

FIG. 7 illustrates a 3^{rd} embodiment of the present disclosure. A substrate processing system 700 comprising a reaction chamber 710, a radio frequency (RF) generator 715, a 714 and a screen circuit 721 connected to the matching unit 714. The reaction chamber 710 may comprise an upper electrode 711 and a lower electrode 712. The upper electrode 711 may be a showerhead and the lower electrode 712 may be a susceptor. A wafer 713 may be placed on the lower electrode 412.

The RF generator 715 generates RF power. The matching unit 714 may be configured to adjust the impedance of the reaction chamber 110 for the generated RF power to be more effective in the wafer processing and the lower electrode 712 is grounded to the ground 730.

The screen circuit 721 may comprise one or more resistances, one or more capacitors, one or more coils and one or more diodes and the screen circuit 721 may produce a voltage which is named as a reference voltage (V_{ref}). The controller 722 may be connected to the screen circuit 721 and the controller 722 may be configured to measure and monitor the reference voltage and to calculate a slope value for determining whether the wafer 713 is dechucked.

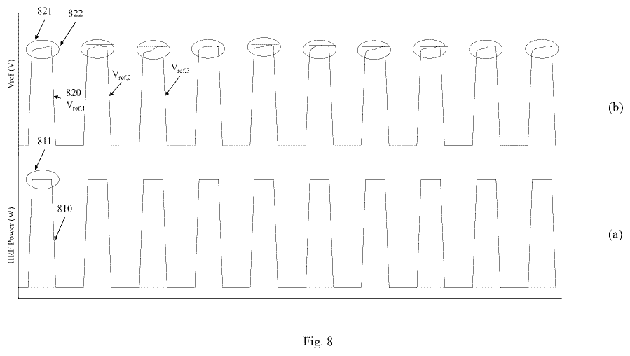

FIG. 8 (a) illustrates an example of High Radio Frequency (HRF) power graphs for multiple cycles generated from RF generator and FIG. 8 (b) illustrates an example of reference voltages monitored by the controller 722 and each of the extracted maximum values (Vₘₐₓ) from the reference voltages according to a 3^{rd} method embodiment of the present disclosure.

At the same moment of the HRF power cycle 810, a reference voltage 820 appears. But with the screen circuit 721, the top of the voltage 821 may not be as flat as that of the HRF power 811. From this non-flat top of the voltage 821, the maximum value 822 may be derived.

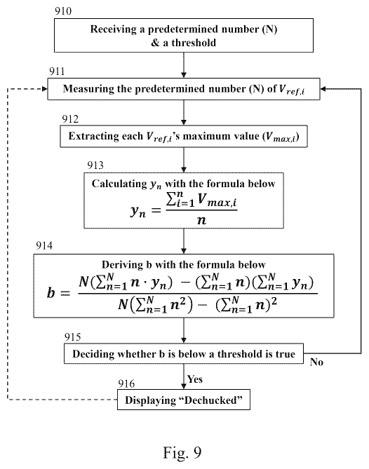

FIG. 9 explains the 3^{rd} method embodiment of the present disclosure.

In steps 910 and 911 of the method, the controller 722 may be configured to receive parameters such as a predetermined number N and a threshold for slope decision and the controller 722 may also be configured to measure N reference voltages (V_{ref,1}, V_{ref,2}, V_{ref,3}, . . . . V_{ref,N-1}, V_{ref,N}).

After N reference voltages measurement, in a step 912 of the method, the controller 722 may be configured to extract maximum values of each of the reference voltages (V_{max,1}, V_{max,2}, V_{max,3}, . . . , V_{max,N-1}, V_{max,N}). Then in a step 913 of the method, the controller 722 may be configured to calculate yₙ with an equation [EQ 3] shown below.

$${y}_{n} = \frac{{\sum }_{i = 1}^{n} {V}_{max , i}}{Nn} ( 1 \leq n \leq N ) ; \qquad [ EQ 3 ]$$

Then in a step 914 of the method, the controller 722 may be configured to derive a slope value b with an equation [EQ 4] shown below,

$$b = \frac{N ( {\sum }_{n = 1}^{N} n \cdot {y}_{n} ) - ( {\sum }_{n = 1}^{N} n ) ( {\sum }_{n = 1}^{N} {y}_{n} )}{N ( {\sum }_{n = 1}^{N} {n}^{2} ) - {( {\sum }_{n = 1}^{N} n )}^{2}} . \qquad [ EQ 4 ]$$

Then in a step 915 of the method, the controller 722 may be configured to decide whether the slope value b is below the threshold is true and if it is decided to be true, then in a step 916 of the method, the controller 722 may be configured to display “dechucked”. If it is not decided to be true, the controller 722 may be configured to continue measuring reference voltages.

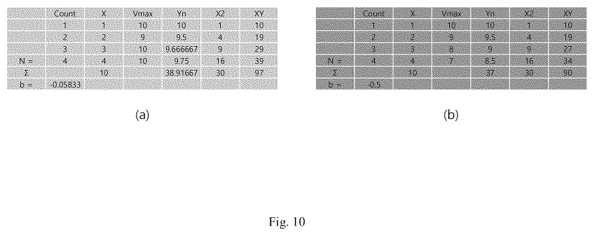

FIG. 10 (a) illustrates an example of getting slope value b with (N=4) case.

The process of calculating yₙ and slope value b may be shown and the process of getting Vₘₐₓ values from V_{ref} graph is omitted for simplicity.

In a step 913 of the method, each yₙ (1≤n≤4) values are derived as follows using EQ 3.

$${y}_{1} = ( {V}_{max , 1} ) / 1 = [ 10 / 1 ] = 10 ;$$

$${y}_{2} = ( {V}_{max , 1} + {V}_{max , 2} ) / 2 = [ ( 10 + 9 ) / 2 ] = 9.5 ;$$

$${y}_{3} = ( {V}_{max , 1} + {V}_{max , 2} + {V}_{max , 3} ) / 3 = [ ( 10 + 9 + 10 ) / 3 ] = 9.667 ;$$

$${y}_{4} = ( {V}_{max , 1} + {V}_{max , 2} + {V}_{max , 3} + {V}_{max , 4} ) / 4 = [ ( 10 + 9 + 10 + 10 ) / 4 ] = 9.75 ;$$

Then in a step 914 of the method, b is derived as follows using EQ 4 below.

$$b = \frac{N ( {\sum }_{n = 1}^{N} n \cdot {y}_{n} ) - ( {\sum }_{n = 1}^{N} n ) ( {\sum }_{n = 1}^{N} {y}_{n} )}{N ( {\sum }_{n = 1}^{N} {n}^{2} ) - {( {\sum }_{n = 1}^{N} n )}^{2}} = \frac{\begin{matrix}4 ( 1 \cdot 10 + 2 \cdot 9.5 + 3 \cdot 9.667 + 4 \cdot 9.75 ) - \\ ( 1 + 2 + 3 + 4 ) ( 10 + 9.5 + 9.667 + 9.75 )\end{matrix}}{4 ( 1 + 4 + 9 + 16 ) - {( 1 + 2 + 3 + 4 )}^{2}} = \frac{388 - 10 \times 38.917}{120 - 100} = - 0.058$$

Therefore, for values of Vₘₐₓ [10, 9, 10, 10] and N=4, the slope value b would be −0.058.

Another example with N=4 is shown in FIG. 10 (b).

For Vₘₐₓ values [10, 9, 8, 7], the slope value b would be derived as follows.

In a step 913 of the method, each yₙ (1≤n=4) values are derived as follows using EQ 3.

$${y}_{1} = ( {V}_{max , 1} ) / 1 = [ 10 / 1 ] = 10 ;$$

$${y}_{2} = ( {V}_{max , 1} + {V}_{max , 2} ) / 2 = [ ( 10 + 9 ) / 2 ] = 9.5 ;$$

$${y}_{3} = ( {V}_{max , 1} + {V}_{max , 2} + {V}_{max , 3} ) / 3 = [ ( 10 + 9 + 8 ) / 3 ] = 9 ;$$

$${y}_{4} = ( {V}_{max , 1} + {V}_{max , 2} + {V}_{max , 3} + {V}_{max , 4} ) / 4 = [ ( 10 + 9 + 8 + 7 ) / 4 ] = 8.5 ;$$

Then in a step 914 of the method, b is derived as follows using EQ 4.

$$b = \frac{N ( {\sum }_{n = 1}^{N} n \cdot {y}_{n} ) - ( {\sum }_{n = 1}^{N} n ) ( {\sum }_{n = 1}^{N} {y}_{n} )}{N ( {\sum }_{n = 1}^{N} {n}^{2} ) - {( {\sum }_{n = 1}^{N} n )}^{2}} = \frac{\begin{matrix}4 ( 1 \cdot 10 + 2 \cdot 9.5 + 3 \cdot 9 + 4 \cdot 8.5 ) - \\ ( 1 + 2 + 3 + 4 ) ( 10 + 9.5 + 9 + 8.5 )\end{matrix}}{4 ( 1 + 4 + 9 + 16 ) - {( 1 + 2 + 3 + 4 )}^{2}} = \frac{360 - 10 \times 37}{120 - 100} = - 0.5$$

For values of Vₘₐₓ [10, 9, 8, 7] and N=4, the slope value b would be −0.5.

When a wafer is well chucked, the slope value b may be zero (0) or very close to zero (0). The threshold for deciding whether may vary based on the specifics of system and requirements.

If the threshold may be set to be ‘−0.1’, FIG. 10 (a)'s slope value (−0.05833) is greater than the threshold while that of FIGS. 10 (b) (−0.5) is smaller than the threshold. Therefore, in a step 915 of the method, the controller 722 may be configured to decide whether b is below the threshold.

In case of FIG. 10 (b), in a step 916 of the method, the controller 722 may be configured to display “dechucked”. But in FIG. 10 (a), in a step 911 of the method, the controller 722 may be configured to measure reference voltages.

The above-described arrangement of system and method are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A substrate processing system with capabilities to detect whether a wafer is dechucked during processing, the system comprising:
a reaction chamber provided with an upper electrode and a lower electrode, and configured to process a wafer;
a radio frequency (RF) generator configured to generate a high frequency power to in the reaction chamber;
a matching unit disposed between the reaction chamber and the RF generator and configured to adjust the impedance of the reaction chamber for the generated high frequency power to be more effective in the processing;
a phase shift detector connected to the reaction chamber in parallel and configured to detect a phase shift between a signal going into the upper electrode and a signal coming out of the lower electrode; and
a controller connected to the phase shift detector and configured to receive parameters, to determine and to display a chucking status of the wafer.

2. The substrate processing system according to the claim 1, further comprising:
a first attenuator disposed between the upper electrode and the phase shift detector; and
a second attenuator disposed between the phase shift detector and the lower electrode.

3. A method to detect whether a wafer is dechucked in a substrate processing system according to claim 1, the method comprises:
receiving a first threshold, a second threshold and a minimum time length;
measuring phase shift degrees from the upper electrode and the lower electrode;
determining whether the measured phase shift degrees are not within the first and the second thresholds and the measured phase shift degrees last as long as the minimum time length is true; and
displaying a dechucked status if determined to be true and repeat the measuring step if determined to be false.

4. A substrate processing system with capabilities to detect whether a wafer is dechucked during processing, the system comprising:
a reaction chamber provided with an upper electrode and a lower electrode, and configured to process the wafer;
a radio frequency (RF) generator configured to generate a high frequency signal to process the wafer in the reaction chamber;
a matching unit disposed between the reaction chamber and the RF generator and configured to adjust the impedance of the reaction chamber for the generated high frequency power to be more effective in the processing;
a network analyzing unit connected to the reaction chamber in parallel and configured to detect a transmission coefficient of the reaction chamber; and
a controller connected to the network analyzing unit and configured to receive parameters, to determine, and to display a dechucked status of the wafer.

5. The substrate processing system according to claim 4, the system comprising:
a first low pass filter (LPF) disposed between the upper electrode and the network analyzing unit; and
a second LPF disposed between the network analyzing unit and the lower electrode.

6. The substrate processing system according to claim 4, wherein the network analyzing unit is a vector network analyzer.

7. The substrate processing system according to claim 4, wherein the transmission coefficient is calculated by a formula below,
S₂₁=Sₒᵤₜ/Sᵢₙ, (S₂₁: transmission coefficient, Sₒᵤₜ: Signal going out from the first LPF, Sᵢₙ: Signal coming into the second LPF).

8. A method to detect whether a wafer is dechucked in a substrate processing system according to claim 4, the method comprises:
receiving a threshold;
measuring a transmission coefficient from the reaction chamber;
determining whether the measured transmission coefficient is greater than the threshold is true; and
displaying dechucked if determined to be true and repeat the measuring step if determined to be false.

9. The method according to claim 8, wherein the transmission coefficient is calculated by a formula below,
S₂₁=Sₒᵤₜ/Sᵢₙ, (S₂₁: transmission coefficient, Sₒᵤₜ: Signal going out from the first LPF, Sᵢₙ: Signal coming into the second LPF).

10. A substrate processing system with capabilities to detect whether a wafer is dechucked during processing, the system comprises:
a reaction chamber configured to process the wafer;
a radio frequency (RF) generator configured to generate a high frequency power to process the wafer in the reaction chamber;
a matching unit disposed between the reaction chamber and the RF generator and configured to adjust the impedance of the reaction chamber for the generated high frequency power to be more effective in the processing;
a screen circuit connected to the matching unit in series and configured to produce a reference voltage used for calculating a slope value (b) to determine whether the wafer is dechucked; and
a controller connected to the screen circuit and configured to monitor the reference voltage and to calculate the slope value and to decide whether the wafer is dechucked.

11. The substrate processing system according to the claim 10, wherein the screen circuit comprises more than one resistance, more than one capacitor, one or more coils and one or more diodes.

12. A method to detect whether a wafer is dechucked in a substrate processing system according to the claim 10, the method comprises:
receiving a predetermined number (N) and a threshold;
measuring N reference voltages (V_{ref,i}) from the screen circuit (1≤i≤N);
extracting maximum values (V_{max,i}) of each of the N reference voltages (V_{ref,i}) (1≤i≤N);
calculating moving average values yₙ (1≤n≤N) with equation 1, wherein equation 1)
$${y}_{n} = \frac{{\sum }_{i = 1}^{n} {V}_{max , i}}{n} ( 1 \leq n \leq N ) ;$$
deriving a slope value b with equation 2, wherein equation 2)
$$b = \frac{N \cdot ( {\sum }_{n = 1}^{N} n \cdot {y}_{n} ) - ( {\sum }_{n = 1}^{N} n ) \cdot ( {\sum }_{n = 1}^{N} {y}_{n} )}{N \cdot ( {\sum }_{n = 1}^{N} {n}^{2} ) - {( {\sum }_{n = 1}^{N} n )}^{2}} ;$$
deciding whether the slope value b is less than the threshold is true; and
displaying dechucked if decided to be true and repeat the measuring step if decided to be false.
